(19) United States
(12) Patent Application Publication
(10) Pub. No.: US 2026/0117393 A1
(43) Pub. Date: Apr. 30, 2026

(54) ETCHING AGENT COMPOSITION AND ETCHING METHOD USING THE SAME

(71) Applicant: KCTECH CO., LTD., Anseong-si (KR)

(72) Inventors: Yo Han KIM, Anseong-si (KR); Hyung Pyo HONG, Seongnam-si (KR); Jun Woo LEE, Pyeongtaek-si (KR)

(73) Assignee: KCTECH CO., LTD., Anseong-si (KR)

(21) Appl. No.: 19/373,920

(22) Filed: Oct. 30, 2025

(30) Foreign Application Priority Data
Oct. 30, 2024 (KR) 10-2024-0150319

(51) Int. Cl. C23F 1/26

(52) U.S. Cl. CPC C23F 1/26

(57) ABSTRACT

According to an aspect, there is provided an etching agent composition, including an oxidizer, an etchant including a fluorine (F)-containing compound, and an inhibitor including a heterocyclic compound containing one or more of nitrogen (N), sulfur (S), and oxygen (O), the heterocyclic compound having one or more aromatic ring substituents having 6 to 20 carbon atoms. According to another aspect, there is provided a method of etching a target film, the method including preparing a target film including a molybdenum (Mo) film and a titanium silicon nitride (TSN) film, and etching the target film using the etching agent composition.

### CROSS-REFERENCE TO RELATED APPLICATIONS

This application claims the benefit of priority under 35 U.S.C. § 119 to Korean Patent Application No. 10-2024-0150319, filed Oct. 30, 2024, the contents of which are incorporated herein by reference in its entirety.

### BACKGROUND

### 1. Field of the Invention

One or more embodiments relate to an etching agent composition and an etching method using the same.

### 2. Description of the Related Art

Recently, as technology in the semiconductor field has developed dramatically, miniaturization of devices has become possible through high integration of internal circuits of semiconductor devices. Accordingly, electronic devices, including semiconductor devices, have also been able to achieve miniaturization and high portability.

In semiconductor manufacturing processes, in order to manufacture micro semiconductor devices having various functions, introducing two or more types of films having different characteristics onto a substrate to form circuits having complex structures and integrated at high density is essential. For example, various films such as a silicon oxide film, a silicon nitride film, a titanium nitride film, and a polysilicon film may be introduced into semiconductor processes. These various films perform various roles, such as an insulating film, a barrier film, and a stop film, depending on semiconductor processes and devices.

A semiconductor etching process is a process of leaving necessary films according to the characteristics of semiconductor devices to be produced among the various films listed above, and removing other unnecessary films. Such a semiconductor etching process requires an etching process that rapidly and accurately removes films to be removed while simultaneously minimizing effects on other films. Therefore, there is a continuing need for research on etching compositions and etching methods that have a constant selectivity for specific target films while being able to protect other film materials.

### SUMMARY

Embodiments provide an etching agent composition that maintains substantially the same etching rates for a molybdenum (Mo) film and a titanium silicon nitride (TSN) film while causing substantially no etching of other types of films, such as an atomic layer deposition oxide (ALD Oxide) film, a silicon nitride (SiN) film, and a polysilicon (poly-Si) film, thereby protecting target films.

However, technical goals to be achieved are not limited to those described above, and other goals not mentioned above are clearly understood by one of ordinary skill in the art from the following description.

According to an aspect, there is provided an etching agent composition, including an oxidizer, an etchant including a fluorine (F)-containing compound, and an inhibitor including a heterocyclic compound containing one or more of nitrogen (N), sulfur (S), and oxygen (O), the heterocyclic compound having one or more aromatic ring substituents having 6 to 20 carbon atoms.

The oxidizer may include one or more of hydrogen peroxide (H₂O₂), periodic acid, and peracetic acid. The content of the oxidizer may be 0.001 to 10 weight percent (wt %) based on the total weight of the etching agent composition.

The F-containing compound of the etchant may include one or more of hydrogen fluoride, ammonium fluoride, ammonium bifluoride, tetramethylammonium fluoride, tetraethylammonium fluoride, tetrapropylammonium fluoride, tetrabutylammonium fluoride, tetrabutyl fluoride, fluoroboric acid (BF₄H), and fluorosilicic acid (H₂SiF₆). The content of the etchant may be 0.001 to 5 wt % based on the total weight of the etching agent composition.

The aromatic ring substituents having 6 to 20 carbon atoms may include one or more of benzene, naphthalene, and anthracene.

The inhibitor may include one or more of quinine, pyrilamine maleate salt, sulfapyridine, sulfathiazole, omeprazole, 2-phenyl-2-imidazole, 2-phenyl-2-oxazoline, 3-phenyl-1H-pyrazole, benzylaminopurine, 4-(3-phenylpropyl)piperidine, 9,10-bis(4-pyridyl)anthracene, 4-[(E)-2-(9-anthryl)vinyl]pyridine, 4-(naphthalene-2-yl)-1H-imidazopyridine, 2-phenylfuran, 5-phenyl-oxazole, 2-phenylthiophene, 2-phenylthiazole, and 1-[(thiazole-2-yl)azo]-2-naphthol. The content of the inhibitor may be 0.0001 to 5 wt % based on the total weight of the etching agent composition.

The etching agent composition according to an embodiment may further include a pH-adjusting agent. In this case, the pH-adjusting agent may include one or more of hydrochloric acid, sulfuric acid, nitric acid, methanesulfonic acid, p-toluenesulfonic acid, oxalic acid, sulfamic acid, monoethanolamine, diethanolamine, triethanolamine, and propanolamine. The content of the pH-adjusting agent may be 0.01 to 10 wt % based on the total weight of the etching agent composition.

The etching agent composition according to an embodiment may further include a second inhibitor including an azole-based compound. In this case, the content of the second inhibitor may be greater than 0 and less than or equal to 5 wt % based on the total weight of the etching agent composition. The second inhibitor may include one or more of tolyltriazole, oxadiazole, triazole, tetrazole, isoazole, oxazole, isothiazole, isooxazole, imidazole, pyrrole, pyrazole, thienazole, furazole, and thioxazole.

The etching agent composition according to an embodiment may further include an organic solvent including a polar aprotic solvent or a polar protic solvent, wherein the content of the organic solvent may be greater than 0 and less than or equal to 50 wt % based on the total weight of the etching agent composition. The organic solvent may include one or more of dimethyl sulfoxide (DMSO), triethylene glycol dimethyl ether (DMTG), acetamide, N-methylpyrrolidone (NMP), piperazine, morpholine, ethylene glycol monomethyl ether, diethylene glycol monomethyl ether, polyethylene glycol monomethyl ether, ethylene glycol monoethyl ether, diethylene glycol monoethyl ether, triethylene glycol monoethyl ether, polyethylene glycol monoethyl ether, ethylene glycol dimethyl ether, diethylene glycol dimethyl ether, diethylene glycol diethyl ether, diethylene glycol methyl ethyl ether, diethylene glycol methyl butyl ether, triethylene glycol methyl butyl ether, propylene glycol dimethyl ether, dipropylene glycol dimethyl ether, and butyl carbitol.

The pH of the etching agent composition according to an embodiment may be 0 to 4.

A target film to be etched by the etching agent composition according to an embodiment may include a Mo film and a TSN film.

According to another aspect, there is provided a method of etching a target film, the method including preparing a target film including a Mo film and a TSN film. In addition, the method may include etching the target film using the etching agent composition. In this case, the etching agent composition may include an oxidizer, an etchant including an F-containing compound, and an inhibitor including a heterocyclic compound containing one or more of N, S, and O, the heterocyclic compound having one or more aromatic ring substituents having 6 to 20 carbon atoms.

Additional aspects of embodiments will be set forth in part in the description which follows and, in part, will be apparent from the description, or may be learned by practice of the disclosure.

According to embodiments, the etching agent composition causes substantially no etching of target films, such as an ALD oxide film, a SiN film, and a poly-Si film, thereby protecting the target films.

In addition, etching rates for a Mo film and a TSN film are maintained substantially the same, thereby achieving selective etching of target films. Also, the etching ratio of the Mo film to the TSN film may be maintained in a range of about 0.5:1 to 1:1.

Furthermore, when forming patterns in a target film in which a Mo film and a TSN film are laminated, uniform circuit line widths and the like can be effectively implemented.

The effects of the disclosure are not limited to the above-described effects, and should be understood to include all effects that are inferable from the configurations of the disclosure described in the detailed description or claims of the disclosure.

### DETAILED DESCRIPTION

Hereinafter, the terminology used herein is for the purpose of describing particular embodiments only and is not to be limiting of the embodiments. The singular forms “a”, “an”, and “the” are intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

Unless otherwise defined, all terms including technical and scientific terms used herein have the same meaning as commonly understood by one of ordinary skill in the art to which the embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

In the description of embodiments, detailed description of well-known related structures or functions will be omitted when it is deemed that such description will cause ambiguous interpretation of the present disclosure.

In addition, the terms first, second, A, B, (a), and (b) may be used to describe components of the embodiments. These terms are used only for the purpose of discriminating one component from another component, and the nature, the sequences, or the orders of the components are not limited by the terms. It should be noted that if one component is described as being “connected,” “coupled” or “joined” to another component, the former may be directly “connected,” “coupled,” and “joined” to the latter or “connected”, “coupled”, and “joined” to the latter via another component.

A component, which has the same common function as a component included in any one embodiment, will be described by using the same name in other embodiments. Unless disclosed to the contrary, the description of any one embodiment may be applied to other embodiments, and the specific description of the repeated configuration will be omitted.

It is understood that the term “about” refers to a range of numbers that a person skilled in the art would consider equivalent to the stated value in terms of achieving the same function or result. When the term “about” is used with a number or value, the term “about” refers to ±20% of the number or value, mainly ±10% of the number or value, often ±5% of the number or value, or ±2% of the number or value. In some aspects, the term “about” may refer to the number or value itself.

As used herein, “A or B”, “at least one of A and B”, “at least one of A or B”, “A, B or C”, “at least one of A, B and C”, and “at least one of A, B, or C,” each of which may include any one of the items listed together in the corresponding one of the phrases, or all possible combinations thereof.

### [Etching Agent Composition]

According to an aspect, there is provided an etching agent composition, including an oxidizer, an etchant including a fluorine (F)-containing compound, and an inhibitor including a heterocyclic compound containing one or more of nitrogen (N), sulfur (S), and oxygen (O), the heterocyclic compound having one or more aromatic ring substituents having 6 to 20 carbon atoms.

The oxidizer in the etching agent composition according to an embodiment serves to etch specific target films, particularly a molybdenum (Mo) film and a titanium silicon nitride (TSN) film. For example, the oxidizer may include one or more of hydrogen peroxide (H₂O₂), periodic acid, and peracetic acid.

The oxidizer may be included in an amount of 0.001 to 10 weight percent (wt %) based on the total weight of the etching agent composition, specifically 0.005 to 5 wt %, more specifically 0.005 to 1 wt %, or 0.005 to 0.05 wt %, or 0.008 to 0.03 wt %. When the content of the oxidizer is within the above range, a rapid rise in metal ion concentration that promotes decomposition of the oxidizer within a desired etching time is prevented, thereby providing greater stability from heat generation and composition changes. On the other hand, when the content of the oxidizer falls below the lower limit of the range, a sufficient etching rate may not be secured. When the content of the oxidizer exceeds the upper limit of the range, control of the etching rate for metal films becomes difficult, which may cause problems in adjusting selectivity for a Mo film and a TSN film to a uniform level.

The etchant in the etching agent composition according to an embodiment may include a F-containing compound. The etching of specific target films, particularly a Mo film and a TSN film, may be achieved by ionization of fluorine in the F-containing compound.

The F-containing compound may include, but is not limited to, one or more of hydrogen fluoride, ammonium fluoride, ammonium bifluoride, tetramethylammonium fluoride, tetraethylammonium fluoride, tetrapropylammonium fluoride, tetrabutylammonium fluoride, tetrabutyl fluoride, fluoroboric acid (BF₄H), and fluorosilicic acid (H₂SiF₆), and may preferably be hydrogen fluoride (HF) or ammonium fluoride (NH₄F). HF and NH₄F not only secure excellent etching rates but are also excellent in terms of safety.

The etchant may be included in an amount of 0.001 to 5 wt % based on the total weight of the etching agent composition, preferably 0.005 to 3 wt %, more preferably 0.01 to 2 wt %, and even more preferably 0.02 to 1 wt %. When the content of the etchant falls below the lower limit of the range, controlling selectivity may be difficult due to a decrease in etching rate for a TSN film. When the content of the etchant exceeds the upper limit of the range, damage to films to be protected (a silicon film, a polysilicon (poly-Si) film, an oxide film, a silicon nitride (SiN) film, and the like) may occur, which may cause pattern defects.

The inhibitor in the etching agent composition according to an embodiment controls etching rates for an atomic layer deposition oxide (ALD Oxide) film, a tetraethyl orthosilicate (TEOS) film, an SiN film, and a poly-Si film, thereby suppressing etching of these films. Through this, films other than a Mo film and a TSN film are effectively protected.

The inhibitor may include a heterocyclic compound containing one or more of N, S, and O, the heterocyclic compound having one or more aromatic ring substituents having 6 to 20 carbon atoms. The aromatic ring substituents may have 6 to 20 carbon atoms, preferably 6 to 14 carbon atoms. Specific examples of the aromatic ring substituents may be benzene, naphthalene, or anthracene.

The inhibitor having such aromatic ring substituents may include, for example, but is not limited to, one or more of quinine, pyrilamine maleate salt, sulfapyridine, sulfathiazole, omeprazole, 2-phenyl-2-imidazole, 2-phenyl-2-oxazoline, 3-phenyl-1H-pyrazole, benzylaminopurine, 4-(3-phenylpropyl)piperidine, 9,10-bis(4-pyridyl)anthracene, 4-[(E)-2-(9-anthryl)vinyl]pyridine, 4-(naphthalene-2-yl)-1H-imidazopyridine, 2-phenylfuran, 5-phenyl-oxazole, 2-phenylthiophene, 2-phenylthiazole, and 1-[(thiazole-2-yl)azo]-2-naphthol, and may preferably be benzylaminopurine, sulfapyridine, 3-phenyl-1H-pyrazole, 2-phenylthiophene, 2-phenylthiazole, 1-[(thiazole-2-yl)azo]-2-naphthol, and/or 2-phenylfuran.

The inhibitor may be included in an amount of 0.0001 to 5 wt % based on the total weight of the etching agent composition, preferably 0.01 to 3 wt %, more preferably 0.1 to 2 wt %, and even more preferably 0.3 to 1.5 wt %. When the content of the inhibitor is within the above range, the instability of the etching agent composition due to decomposition reactions of the oxidizer and etchant during etching is suppressed. When the content of the inhibitor falls below the lower limit of the range, the etching rate for metal films significantly decreases, which may fail to exert a sufficient inhibitory effect. When the content of the inhibitor exceeds the upper limit of the range, precipitation may occur due to exceeding solubility.

As described above, the etching agent composition according to an embodiment includes specific amounts of a specific etchant and a specific inhibitor simultaneously, thereby securing etching rates for a Mo film and a TSN film at similar levels.

The etching agent composition according to an embodiment may further include a pH-adjusting agent. The pH-adjusting agent may be used in the following amounts to adjust the pH of the etching agent composition to an appropriate level. In this case, specific types of the pH-adjusting agent may include one or more of hydrochloric acid, sulfuric acid, nitric acid, methanesulfonic acid, p-toluenesulfonic acid, oxalic acid, sulfamic acid, monoethanolamine, diethanolamine, triethanolamine, and propanolamine. The pH-adjusting agent may be included in an amount of 0.01 to 10 wt % based on the total weight of the etching agent composition, specifically 0.1 to 7 wt %, more specifically 0.5 to 5 wt %, and even more specifically 1 to 4 wt %. The pH-adjusting agent may be used in an appropriate amount to adjust the pH of the etching agent composition to a desired pH range.

In addition, when the etching agent composition according to an embodiment includes the pH-adjusting agent as described above, the pH of the etching agent composition may be 0 to 4, preferably 0.5 to 2. When the pH is outside the range, the etching reaction with fluorine compounds may not proceed properly, and the protective effect of the inhibitor on an ALD oxide film, a TEOS film, a SiN film, and a poly-Si film may be reduced.

The etching agent composition according to an embodiment may further include a second inhibitor.

The second inhibitor, together with the inhibitor described above, may protect target films from etchants and oxidizers including F-containing compounds, and azole-based compounds may be used to perform this role. When azole-based compounds are used, the etching rate of metal films may be slightly reduced, and stable etching rates may be maintained when the etching process is prolonged. Specific types of the second inhibitor may include one or more of tolyltriazole, oxadiazole, triazole, tetrazole, isoazole, oxazole, isothiazole, isooxazole, imidazole, pyrrole, pyrazole, thienazole, furazole, and thioxazole.

The second inhibitor is a component that may be additionally included in the etching agent composition, and may be included in an amount of 0 to 5 wt % based on the total weight of the etching agent composition, specifically greater than 0 and 3 wt % or less, more specifically greater than 0 and 2 wt % or less.

The etching agent composition according to an embodiment may further include an organic solvent. The organic solvent includes a polar aprotic solvent or a polar protic solvent. A specific example of the organic solvent may include one or more of dimethyl sulfoxide (DMSO), triethylene glycol dimethyl ether (DMTG), acetamide, N-methylpyrrolidone (NMP), piperazine, morpholine, ethylene glycol monomethyl ether, diethylene glycol monomethyl ether, polyethylene glycol monomethyl ether, ethylene glycol monoethyl ether, diethylene glycol monoethyl ether, triethylene glycol monoethyl ether, polyethylene glycol monoethyl ether, ethylene glycol dimethyl ether, diethylene glycol dimethyl ether, diethylene glycol diethyl ether, diethylene glycol methyl ethyl ether, diethylene glycol methyl butyl ether, triethylene glycol methyl butyl ether, propylene glycol dimethyl ether, and dipropylene glycol dimethyl ether, and may preferably be butyl carbitol.

The organic solvent is a component that may be additionally included in the etching agent composition. The organic solvent may be included in an amount of 0 to 50 wt % based on the total weight of the etching agent composition, specifically greater than 0 and less than or equal to 50 wt %, more specifically 5 to 30 wt %, and even more specifically 10 to 20 wt %.

In the etching agent composition according to an embodiment, water may account for the remainder to 100% of the sum of wt % of other components excluding water in all etching agent compositions, even if not explicitly mentioned. The water used in an embodiment may be semiconductor-grade water or ultrapure water.

The etching agent composition according to an embodiment may be used for target films, including a Mo film and a TSN film.

According to an embodiment, the etching rate of the etching agent composition for a Mo film may be 5 to 20 Å/min, and the etching rate for a TSN film may be 5 to 20 Å/min. In addition, the etching rate ratio of a Mo film to a TSN film may be 0.5 to 1:1.

Furthermore, the etching rate for a silicon oxide film, an ALD oxide film, a SiN film, or a poly-Si film may be 1 Å/min or less.

### [Etching Method]

The etching agent composition according to an embodiment may be used for etching target films, including a Mo film and a TSN film. The method of etching the target films may specifically include preparing a target film including a Mo film and a TSN film, and etching the target film using the etching agent composition.

In this case, since the etching agent composition is substantially the same as the etching agent composition described in detail above, repeated description thereof is omitted below.

Through the etching method, a Mo film and a TSN film may be etched at etching rates of about 5 to 20 Å/min at an etching process temperature of about 50 to 70° C., while etching rates of 1 Å/min or less may be implemented for other ALD Oxide films, SiN films, and poly-Si films.

Hereinafter, the disclosure will be described in more detail through examples. The following examples are described for the purpose of illustrating the disclosure, and the scope of the disclosure is not limited thereto.

### EXAMPLES

### 1) Preparation Method: Preparation of Etching Agent Composition

According to the compositions in Table 1 below, etching solutions of Examples 1 to 17 and Comparative Examples 1 to 13 were prepared.

Examples 6 and 7 were prepared with the same composition as Example 1, except that 0.42 wt % of tolyltriazole and 0.3 wt % of imidazole were additionally added as second inhibitors, respectively

TABLE 1

| | Composition (wt %) | | | | | | |
|---|---|---|---|---|---|---|---|
| | | | | pH- | | | |
| | | | | adjusting | Second | | |
| | Oxidizer | Etchant | Inhibitor | agent | inhibitor | DIW | pH |
| Comparative | Periodic acid | HF | — | — | — | Balance | 4.1 |
| Example 1 | 0.01 | 0.025 | — | — | — | | |
| Comparative | Periodic acid | HF | — | Methanesulfonic | — | Balance | 0.8 |
| Example 2 | | | | acid | | | |
| | 0.01 | 0.025 | — | 2 | — | | |
| Comparative | Periodic acid | HF | — | Methanesulfonic | — | Balance | 1.1 |
| Example 3 | | | | acid | | | |
| | 0.01 | 0.025 | — | 1 | — | | |
| Comparative | Periodic acid | HF | — | Methanesulfonic | — | Balance | 0.5 |
| Example 4 | | | | acid | | | |
| | 0.01 | 0.025 | — | 5 | — | | |
| Comparative | Periodic acid | HF | — | Phosphoric | — | Balance | 0.7 |
| Example 5 | | | | acid | | | |
| | 0.01 | 0.025 | — | 10 | — | | |
| Comparative | Periodic acid | NH₄F | — | Methanesulfonic | — | Balance | 1 |
| Example 6 | | | | acid | | | |
| | 0.01 | 0.045 | — | 2 | — | | |
| Comparative | Periodic acid | NH₄F | — | Methanesulfonic | — | Balance | 0.5 |
| Example 7 | | | | acid | | | |
| | 0.01 | 0.045 | — | 5 | — | | |
| Comparative | Periodic acid | NH₄F | 4- | Methanesulfonic | — | Balance | 0.9 |
| Example 8 | | | Methylpyridine | acid | | | |
| | 0.01 | 0.045 | 1 | 2 | — | | |
| Comparative | Periodic acid | HF | 4- | Methanesulfonic | — | Balance | 0.9 |
| Example 9 | | | Methylpyridine | acid | | | |
| | 0.01 | 0.025 | 1 | 2 | — | | |
| Comparative | Periodic acid | NH₄F | 4- | Methanesulfonic | — | Balance | 0.9 |
| Example 10 | | | Methylpurine | acid | | | |
| | 0.01 | 0.045 | 1.1 | 2 | — | | |
| Comparative | Periodic acid | HF | 4- | Methanesulfonic | — | Balance | 0.9 |
| Example 11 | | | Methylpurine | acid | | | |
| | 0.01 | 0.025 | 1.1 | 2 | — | | |
| Comparative | H₂O₂ | HF | — | Methanesulfonic | — | Balance | 1 |
| Example 12 | | | | acid | | | |
| | 0.1 | 0.025 | — | 2 | — | | |
| Comparative | Peracetic acid | HF | — | Methanesulfonic | — | Balance | 1.2 |
| Example 13 | | | | acid | | | |
| | 0.2 | 0.025 | — | 2 | — | | |
| Example 1 | Periodic acid | HF | Benzylamino | Methanesulfonic | — | Balance | 0.9 |
| | | | purine | acid | | | |
| | 0.01 | 0.025 | 1.35 | 2 | — | | |
| Example 2 | Periodic acid | NH₄F | Benzylamino | Methanesulfonic | — | Balance | 0.9 |
| | | | purine | acid | | | |
| | 0.01 | 0.045 | 1.35 | 2 | — | | |
| Example 3 | Periodic acid | HF | Sulfapyridine | Methanesulfonic | — | Balance | 0.8 |
| | | | | acid | | | |
| | 0.01 | 0.025 | 0.5 | 2 | — | | |
| Example 4 | Periodic acid | NH₄F | Sulfapyridine | Methanesulfonic | — | Balance | 0.9 |
| | | | | acid | | | |
| | 0.01 | 0.06 | 0.5 | 2 | — | | |
| Example 5 | Periodic acid | HF | 3-Phenyl-1H- | Methanesulfonic | — | Balance | 0.85 |
| | | | pyrazole | acid | | | |
| | 0.01 | 0.025 | 0.6 | 2 | — | | |
| Example 6 | Periodic acid | HF | Benzylamino | Methanesulfonic | Tolyltriazole | Balance | 0.6 |
| | | | purine | acid | | | |
| | 0.01 | 0.025 | 1.35 | 2 | 0.42 | | |
| Example 7 | Periodic acid | HF | Benzylamino | Methanesulfonic | Imidazole | Balance | 0.6 |
| | | | purine | acid | | | |
| | 0.01 | 0.025 | 1.35 | 2 | 0.3 | | |
| Example 8 | Periodic acid | NH₄F | Benzylamino | Methanesulfonic | — | Balance | 0.9 |
| | | | purine | acid | | | |
| | 0.01 | 0.06 | 1.35 | 2 | — | | |
| Example 9 | Periodic acid | HF | 2- | Methanesulfonic | — | Balance | 1.0 |
| | | | Phenylthiophene | acid | | | |
| | 0.01 | 0.025 | 0.6 | 2 | — | | |
| Example 10 | Periodic acid | NH₄F | 2- | Methanesulfonic | — | Balance | 1.0 |
| | | | Phenylthiophene | acid | | | |
| | 0.01 | 0.045 | 0.6 | 2 | — | | |
| Example 11 | H₂O₂ | NH₄F | Benzylamino | Methanesulfonic | — | Balance | 1.1 |
| | | | purine | acid | | | |
| | 0.01 | 0.045 | 0.8 | 2 | — | | |
| Example 12 | Periodic acid | NH₄F | Benzylamino | Methanesulfonic | — | Balance | 1 |
| | | | purine | acid | | | |
| | 0.01 | 0.045 | 0.5 | 2 | — | | |
| Example 13 | Periodic acid | HF | 1-[(Thiazole- | Methanesulfonic | — | Balance | 0.6 |
| | | | 2-yl)azo]-2-naphthol | acid | | | |
| | 0.01 | 0.05 | 0.5 | 3.5 | — | | |
| Example 14 | Periodic acid | NH₄F | 1-[(Thiazole- | Methanesulfonic | — | Balance | 0.7 |
| | | | 2-yl)azo]-2-naphthol | acid | | | |
| | 0.01 | 0.07 | 0.5 | 3.5 | — | | |
| Example 15 | Periodic acid | HF | 1-[(Thiazole- | Methanesulfonic | — | Balance | 0.7 |
| | | | 2-yl)azo]-2-naphthol | acid | | | |
| | 0.01 | 0.05 | 0.5 | 3.5 | — | | |
| Example 16 | Periodic acid | HF | 2-Phenylfuran | Methanesulfonic | — | Balance | 0.7 |
| | | | | acid | | | |
| | 0.01 | 0.025 | 1.1 | 3 | — | | |
| Example 17 | Periodic acid | NH₄F | 2-Phenylfuran | Methanesulfonic | — | Balance | 0.7 |
| | | | | acid | | | |
| | 0.01 | 0.045 | 1.1 | 3 | — | | |

### 2) Evaluation Method: Etch Rate Evaluation of Etching Agent Composition

Test coupons were prepared by cutting TEOS, SiN, TSN, and Mo coupons to 2×2 cm size. Thereafter, the pre-film thicknesses of the test coupons were measured using FilmMetrix and 4Point Probe. The prepared etching agent compositions of Comparative Examples 1 to 13 and Examples 1 to 17 were heated to 60° C., and the test coupons were immersed in the etching agent compositions for 1 to 10 minutes, then removed and rinsed with flowing deionized water (DIW) for 30 seconds. Thereafter, the test coupons were dried with N₂ gas, and the post-film thicknesses were measured using FilmMetrix.

Etch rates were calculated using the following equation, and the etch rates and selectivity are shown in Table 2 below.

$$Etch Rate = [ Pre - film thickness - Post - film thickness ] / Treatment time$$

TABLE 2

Etch Rate [Å/min]

| | Mo | TSN | TEOS | SiN | poly-Si |
|---|---|---|---|---|---|
| Comparative | 30.3 | 0.8 | 0.5 | 0.4 | 0.4 |
| Example 1 | | | | | |
| Comparative | 214 | 18.8 | 0.5 | 0.4 | 0.4 |
| Example 2 | | | | | |
| Comparative | 168.5 | 12.6 | 0.3 | 0.5 | 0.5 |
| Example 3 | | | | | |
| Comparative | 128.5 | 12.6 | 0.6 | 0.8 | 0.8 |
| Example 4 | | | | | |
| Comparative | 65.3 | 2.6 | 0.2 | 0.4 | 0.4 |
| Example 5 | | | | | |
| Comparative | 113.5 | 12.66 | 1 | 0.6 | 0.6 |
| Example 6 | | | | | |
| Comparative | 122.2 | 15.1 | 0.8 | 0.4 | 0.4 |
| Example 7 | | | | | |
| Comparative | 88.1 | 14.4 | 0.7 | 0.5 | 0.6 |
| Example 8 | | | | | |
| Comparative | 76.3 | 12.2 | 0.6 | 0.8 | 1 |
| Example 9 | | | | | |
| Comparative | 81.2 | 13.2 | 1 | 0.4 | 0.6 |
| Example 10 | | | | | |
| Comparative | 73.8 | 12.5 | 1.1 | 0.6 | 0.5 |
| Example 11 | | | | | |
| Comparative | 130.5 | 8.4 | 1 | 0.8 | 0.6 |
| Example 12 | | | | | |
| Comparative | 80.6 | 6.2 | 0.8 | 0.4 | 0.6 |
| Example 13 | | | | | |
| Example 1 | 12.5 | 11.3 | 0.1 | 0.2 | 0.2 |
| Example 2 | 11.8 | 11.6 | 0.2 | 0.1 | 0.2 |
| Example 3 | 9.8 | 10.2 | 0.2 | 0.1 | 0.1 |
| Example 4 | 14.2 | 15.3 | 0.1 | 0.08 | 0.3 |
| Example 5 | 8.6 | 9.2 | 0.2 | 0.3 | 0.3 |
| Example 6 | 10.1 | 9.8 | 0.05 | 0.1 | 0.1 |
| Example 7 | 8.2 | 9.3 | 0.2 | 0.3 | 0.1 |
| Example 8 | 17.2 | 16.8 | 0.2 | 0.2 | 0.1 |
| Example 9 | 10.3 | 9.8 | 0.2 | 0.1 | 0.05 |
| Example 10 | 11.2 | 10.9 | 0.05 | 0.2 | 0.04 |
| Example 11 | 7 | 6.7 | 0.2 | 0.05 | 0.1 |
| Example 12 | 4.3 | 4.8 | 0.1 | 0.1 | 0.1 |
| Example 13 | 13.2 | 14 | 0.3 | 0.05 | 0.2 |
| Example 14 | 14.3 | 15 | 0.1 | 0.2 | 0.04 |
| Example 15 | 13.2 | 14.8 | 0.1 | 0.05 | 0.1 |
| Example 16 | 9.8 | 10.1 | 0.1 | 0.2 | 0.15 |
| Example 17 | 9.4 | 9.8 | 0.15 | 0.2 | 0.2 |

Based on the etch rate results shown in Table 2 for the etching agent compositions of Table 1, the etching agent compositions of Examples 1 to 17, which include heterocyclic compounds containing one or more of N, S, and O with one or more aromatic ring substituents having 6 to 20 carbon atoms (combined with benzene, naphthalene, or anthracene) as inhibitors, exhibited a balanced selectivity ratio close to 1:1 for Mo and TSN target films. This is in contrast to cases without inhibitors (Comparative Examples 1 to 7 and 12 to 13) or cases with heterocyclic compounds (pyridine or purine) that simply contain one or more of N, S, and O without aromatic ring substituents having 6 to 20 carbon atoms (without combination with benzene, naphthalene, or anthracene) (Comparative Examples 8 to 11). It was further confirmed that lower etch rates were exhibited for other films, such as a TEOS film, a SiN film, and a poly-Si film.

Accordingly, by including heterocyclic compounds containing one or more of N, S, and O with one or more aromatic ring substituents having 6 to 20 carbon atoms (combined with benzene, naphthalene, or anthracene) in the etching agent composition, high selectivity for a Mo film and a TSN film can be achieved relative to a TEOS film, a SiN film, and a poly-Si film, while a Mo film and a TSN film can be etched at substantially equivalent selectivity levels (about 1:1). This enables rapid and accurate removal of target films while minimizing effects on other films. Furthermore, the etching agent compositions are found to be particularly suitable for processes of forming metal gate recesses in film stacks, where a TSN film, serving as a metal barrier layer, and a Mo film, serving as a wordline metal, are laminated during semiconductor etching processes.

It will be apparent to one of ordinary skill in the art that various alterations and modifications can be made from the above description. For example, suitable results may be achieved if the described techniques are performed in a different order, and/or if the described components are combined in a different manner, and/or replaced or supplemented by other components or their equivalents.

Therefore, other implementations, other embodiments, and equivalents to the claims are also within the scope of the following claims.

What is claimed is:

1. An etching agent composition, comprising:
an oxidizer;
an etchant comprising a fluorine (F)-containing compound; and
an inhibitor comprising a heterocyclic compound containing one or more of nitrogen (N), sulfur (S), and oxygen (O), the heterocyclic compound having one or more aromatic ring substituents having 6 to 20 carbon atoms.

2. The etching agent composition of claim 1, wherein the oxidizer comprises one or more of hydrogen peroxide (H₂O₂), periodic acid, and peracetic acid.

3. The etching agent composition of claim 1, wherein the F-containing compound comprises one or more of hydrogen fluoride, ammonium fluoride, ammonium bifluoride, tetramethylammonium fluoride, tetraethylammonium fluoride, tetrapropylammonium fluoride, tetrabutylammonium fluoride, tetrabutyl fluoride, fluoroboric acid (BF₄H), and fluorosilicic acid (H₂SiF₆).

4. The etching agent composition of claim 1, wherein the aromatic ring substituents having 6 to 20 carbon atoms comprise one or more of benzene, naphthalene, and anthracene.

5. The etching agent composition of claim 1, wherein the inhibitor comprises one or more of quinine, pyrilamine maleate salt, sulfapyridine, sulfathiazole, omeprazole, 2-phenyl-2-imidazole, 2-phenyl-2-oxazoline, 3-phenyl-1H-pyrazole, benzylaminopurine, 4-(3-phenylpropyl)piperidine, 9,10-bis(4-pyridyl)anthracene, 4-[(E)-2-(9-anthryl)vinyl]pyridine, 4-(naphthalene-2-yl)-1H-imidazopyridine, 2-phenylfuran, 5-phenyl-oxazole, 2-phenylthiophene, 2-phenylthiazole, and 1-[(thiazole-2-yl)azo]-2-naphthol.

6. The etching agent composition of claim 1, further comprising a pH-adjusting agent,
wherein the pH-adjusting agent comprises one or more of hydrochloric acid, sulfuric acid, nitric acid, methanesulfonic acid, p-toluenesulfonic acid, oxalic acid, sulfamic acid, monoethanolamine, diethanolamine, triethanolamine, and propanolamine.

7. The etching agent composition of claim 1, further comprising a second inhibitor comprising an azole-based compound,
wherein a content of the second inhibitor is greater than 0 and less than or equal to 5 weight percent (wt %) based on a total weight of the etching agent composition.

8. The etching agent composition of claim 7, wherein the second inhibitor comprises one or more of tolyltriazole, oxadiazole, triazole, tetrazole, isoazole, oxazole, isothiazole, isooxazole, imidazole, pyrrole, pyrazole, thienazole, furazole, and thioxazole.

9. The etching agent composition of claim 1, further comprising an organic solvent including a polar aprotic solvent or a polar protic solvent,
wherein a content of the organic solvent is greater than 0 and less than or equal to 50 wt % based on a total weight of the etching agent composition.

10. The etching agent composition of claim 9, wherein the organic solvent comprises one or more of dimethyl sulfoxide (DMSO), triethylene glycol dimethyl ether (DMTG), acetamide, N-methylpyrrolidone (NMP), piperazine, morpholine, ethylene glycol monomethyl ether, diethylene glycol monomethyl ether, polyethylene glycol monomethyl ether, ethylene glycol monoethyl ether, diethylene glycol monoethyl ether, triethylene glycol monoethyl ether, polyethylene glycol monoethyl ether, ethylene glycol dimethyl ether, diethylene glycol dimethyl ether, diethylene glycol diethyl ether, diethylene glycol methyl ethyl ether, diethylene glycol methyl butyl ether, triethylene glycol methyl butyl ether, propylene glycol dimethyl ether, dipropylene glycol dimethyl ether, and butyl carbitol.

11. The etching agent composition of claim 1, wherein a content of the oxidizer is 0.001 to 10 wt % based on a total weight of the etching agent composition.

12. The etching agent composition of claim 1, wherein
a content of the etchant is 0.001 to 5 wt % based on a total weight of the etching agent composition, and
a content of the inhibitor is 0.0001 to 5 wt % based on the total weight of the etching agent composition.

13. The etching agent composition of claim 6, wherein
a content of the pH-adjusting agent is 0.01 to 10 wt % based on a total weight of the etching agent composition, and
a pH of the etching agent composition is 0 to 4.

14. The etching agent composition of claim 1, wherein a target film to be etched by the etching agent composition comprises a molybdenum (Mo) film and a titanium silicon nitride (TSN) film.

15. A method of etching a target film, the method comprising:
preparing a target film to be etched, comprising a Mo film and a TSN film; and
etching the target film using the etching agent composition of claim 1.
